(19) United States
(12) Patent Application Publication
(10) Pub. No.: US 2018/0342976 A1
(43) Pub. Date: Nov. 29, 2018

(54) MODULAR SOLAR CELL ELECTRICAL POWER GENERATING LAYER FOR LOW EARTH ORBIT SPACE SUITS

(71) Applicant: BOISE STATE UNIVERSITY, Boise, ID (US)

(72) Inventors: Samuel Pederson, Boise, ID (US); Ashita Chandnani, Boise, ID (US); Drew Butler, Boise, ID (US); Sean O'Kelley, Santa Clarita, CA (US)

(21) Appl. No.: 15/989,378

(22) Filed: May 25, 2018

Related U.S. Application Data
(60) Provisional application No. 62/511,155, filed on May 25, 2017.

(51) Int. Cl. H02S 30/20; H01G 9/20; H01L 31/02; H02S 20/30; H01L 25/04

(52) U.S. Cl. CPC H02S 30/20; H01G 9/2095; H01L 25/047; H02S 20/30; H01L 31/02021

(57) ABSTRACT

A system may include a flexible leaf having a fastener, the fastener being electrically conductive, the flexible leaf having a solar cell incorporated therein, the solar cell electrically coupled to the fastener. The system may further include an article of clothing including a respective fastener, the respective fastener being electrically conductive, the flexible leaf configured to couple to the article of clothing via at least the fastener and the respective fastener. The system may also include an electrical circuit incorporated in the article of clothing, the electrical circuit electrically coupled to the respective fastener.

### CROSS-REFERENCE TO RELATED APPLICATIONS

This application is related to and claims the benefit of U.S. Provisional Patent Application Ser. No. 62/511,155 filed on May 25, 2017 and entitled “Modular Solar Cell Electrical Power Generating Layer for Low Earth Orbit Space Suits,” the contents of which are incorporated by reference herein in their entirety.

### GOVERNMENT LICENSE RIGHTS

This invention was made with Government support under contract number NNX15AK35A awarded by NASA. The Government has certain rights in the invention.

### FIELD OF THE DISCLOSURE

This disclosure is generally related to solar cell electrical power generation and in particular to a modular solar cell electrical power generating layer for low earth orbit space suits.

### BACKGROUND

Spacesuits, such as extravehicular mobility units, are an important component in space travel and experimentation. In order to protect the wearer from the harsh environment of low earth orbit and to enable mobility and navigation, spacesuits typically include several electrical systems, such as life support systems, propulsion systems, communications systems, etc. Further, a spacesuit may include a battery powered electrical distribution system to provide power to the various electrical systems.

Power generation is a desirable feature for new generation spacesuits designed for low earth orbit, and other applications. Power generation at the spacesuit itself may enable longer, more productive, and more efficient extravehicular missions. During a typical extravehicular mission, a spacesuit may be exposed to direct sunlight for up to 8 hours. Further, in a low earth orbit, spacecraft and spacesuits may be subjected to a wider spectrum of light produced by the sun.

Typical spacesuits are not equipped to take advantage of the additional light spectrum in low earth orbit. Further, typical solar power generation systems may be too large or bulky for use in a spacesuit. Also, reconfiguring and/or replacing solar cells within a typical power generation system may be a complex task and often requires special tools and expertise.

### SUMMARY

Disclosed are embodiments of a system and method that overcome at least one of the disadvantages discussed above. In an embodiment, a flexible leaf, or pocket, includes a solar cell electrically coupled to conductive fasteners. The conductive fasteners both fasten the leaf to a spacesuit and electrically connect the solar cell to a battery charger. The flexible leaf may be swapped with an identical flexible leaf if desired, giving the system a modular design. Further, multiple flexible leafs may be fastened to the spacesuit in different configurations to produce a desirable current and/or voltage output.

In an embodiment, a system includes a flexible leaf having a fastener, the fastener being electrically conductive, the flexible leaf having a solar cell incorporated therein, the solar cell electrically coupled to the fastener. The system further includes an article of clothing including a respective fastener, the respective fastener being electrically conductive, the flexible leaf configured to couple to the article of clothing via at least the fastener and the respective fastener. The system also includes an electrical circuit incorporated in the article of clothing, the electrical circuit electrically coupled to the respective fastener.

In some embodiments, the fastener is a snap fastener having a first shape and the respective fastener is a complementary snap fastener having a second shape, the first shape configured to interlock with the second shape. In some embodiments, the system includes a second fastener incorporated in the flexible leaf, the second fastener being electrically conductive, and a respective second fastener incorporated in the article of clothing, the respective second fastener being electrically conductive, where the solar cell and the electrical circuit are configured to form at least a portion of a closed circuit loop in response to the fastener being fastened to the respective fastener and the second fastener being fastened to the respective second fastener.

In some embodiments, the article of clothing is a portion of a space suit. In some embodiments, the electrical circuit includes at least a battery configured to be charged at least partially by the solar cell. In some embodiments, the battery is configured to power a propulsion system, an environmental control system, a communication system, or any combinations thereof. In some embodiments, the solar cell is a multi junction Gallium-Arsenide solar cell. In some embodiments, the flexible leaf includes a fabric pocket. In some embodiments, the flexible leaf includes a transparent shield. In some embodiments, the transparent shield is attached to the flexible leaf with thread, the flexible leaf omitting any polymer adhesive. In some embodiments, the transparent shield is attached to the flexible leave with adhesive. In some embodiments, the article of clothing includes a leg portion, a chest portion, a back portion, an arm portion, or any combination thereof, wherein the respective fastener is positioned on the leg portion, on the chest portion, on the back portion, or on the arm portion.

In an embodiment, a system includes a plurality of flexible leaves, each flexible leaf having a pair of conductive fasteners incorporated therein. The system further includes a plurality of solar cells, each of the flexible leaves having at least one of the solar cells incorporated therein. The system also includes an article of clothing including multiple pairs of conductive fasteners incorporated therein, where the plurality of flexible leaves are configured to interchangeably connect to each pair of fasteners.

In some embodiments, the multiple pairs of conductive fasteners are electrically coupled to an electrical circuit in series with each other. In some embodiments, the multiple pairs of fasteners are electrically coupled to an electrical circuit in parallel with each other.

In an embodiment, a method includes generating electrical power at a solar cell incorporated within a flexible leaf having a pair of conductive fasteners and transmitting the electrical power to a circuit incorporated within an article of clothing via the pair of conductive fasteners and via a pair of respective conductive fasteners incorporated in the article of clothing.

In some embodiments, the method includes, before generating the electrical power: coupling a first conductive fastener of the pair of conductive fasteners with a first respective conductive fastener of the pair of respective conductive fasteners; and coupling a second conductive fastener of the pair of conductive fasteners with a second respective conductive fastener of the pair of respective conductive fasteners. In some embodiments, the method includes: uncoupling a first conductive fastener of the pair of conductive fasteners from a first respective conductive fastener of the pair of respective conductive fasteners; and uncoupling a second conductive fastener of the pair of conductive fasteners from a second respective conductive fastener of the pair of respective conductive fasteners. In some embodiments, the method includes uncoupling the flexible leaf from the article of clothing and coupling a second flexible leaf to the article of clothing, the second flexible leaf having a second pair of conductive fasteners. In some embodiments, the method includes charging a battery via the circuit incorporated within the article of clothing.

### BRIEF DESCRIPTION OF THE DRAWINGS

FIG. 1 depicts an embodiment of a system for solar cell electrical power generation.

FIG. 2 depicts an embodiment of a flexible leaf with a solar cell incorporated therein.

FIG. 3 depicts an embodiment of complementary snap fasteners usable with an embodiment of a solar cell electrical power generation system.

FIG. 4 depicts an embodiment of a spacesuit having multiple flexible leaves attached thereto for solar cell electrical power generation.

FIG. 5 depicts an embodiment of a flexible leaf with a solar cell configured for experimental testing.

FIG. 6 depicts experimental results associated with the flexible leaf configuration of FIG. 5.

FIG. 7 is a block diagram depicting an embodiment of a system for solar cell electrical power generation configured in series.

FIG. 8 is a block diagram depicting an embodiment of a system for solar cell electrical power generation configured in parallel.

FIG. 9 is a chart depicting experimental results of an individual and multiple flexible leaves.

FIG. 10 is a flow chart depicting an embodiment of a method for solar power generation.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the scope of the disclosure.

### DETAILED DESCRIPTION

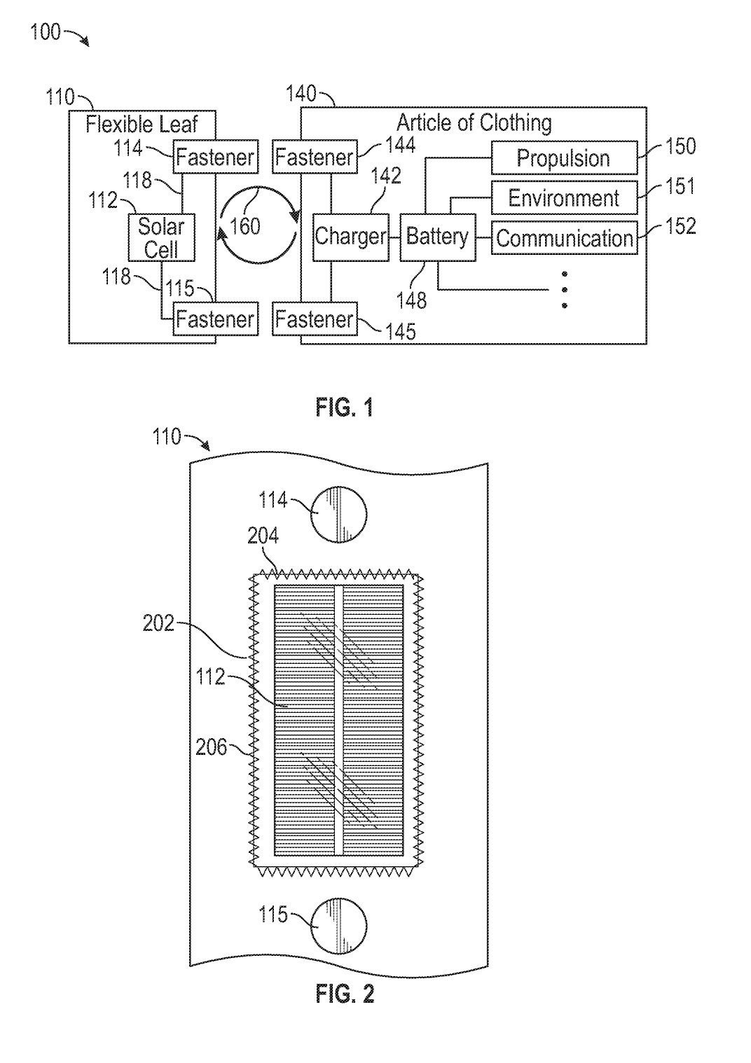

Referring to FIG. 1, an embodiment of a system 100 for solar cell electrical power generation is depicted. The system 100 may include a flexible leaf 110 and an article of clothing 140. As described herein, the flexible leaf 110 may be a flexible pocket and the article of clothing 140 may be a spacesuit, or any portion thereof.

The flexible leaf 110 may include a solar cell 112, a first fastener 114, and a second fastener 115. The fasteners 114, 115 may be electrically conductive. As used herein, to be electrically conductive means that the fasteners 114, 115 may be formed, fully or partially, from an electrically conductive material or the fasteners 114, 115 may include an attached conductive electrode. The solar cell 112 may be electrically coupled to the fasteners 114, 115 through wires 118. The wires 118 may include 0.063-inch gauge copper wire. In some embodiments, the solar cell 112 is a multi junction Gallium-Arsenide solar cell (e.g., an AlInGaP/GaAs/InGaAs triple-junction solar cell), and may be fabricated via metalorganic chemical vapor deposition. The solar cell 112 may be engineered with bandgaps for ultraviolet photon absorption and conversion. The Gallium-Arsenide construction may enable the solar cell 112 to operate more efficiently, converting energy from a larger spectrum of light, than other forms of solar cells in direct sunlight in low earth orbit. Further, Gallium-Arsenide solar cells may have a flexible construction that enables the solar cell 112 to flex along with the flexible leaf 110.

The article of clothing 140 may include a battery charger circuit 142, a first fastener 144, and a second fastener 145. The fasteners 144, 145 may also be electrically conductive and the battery charger circuit 142 may be electrically coupled between the fasteners 144, 145 such that a voltage potential and/or electrical current between the fasteners 144, 145 may be used to power the battery charger circuit 142. The article of clothing 140 may include a battery 148 and multiple electrical systems. For example, as discussed herein, the article of clothing 140 may be a spacesuit and may include a propulsion system 150, an environmental control system 151, a communication system 152, or other types of electrical systems. It should be noted that even though FIG. 1 depicts a battery charger circuit 142, and additional circuitry specific to a spacesuit, in some embodiments other types of clothing and electrical circuits are contemplated and fall within the scope of this disclosure.

In response to the first fastener 114 of the flexible leaf 110 being coupled to the first fastener 144 of the article of clothing 140 and the second fastener 115 of the flexible leaf 110 being coupled to the second fastener 145 of the article of clothing 140, a closed circuit loop 160 may be formed by at least the solar cell 112 and the battery charger circuit 142.

During operation, the fastener 114 of the flexible leaf 110 may be coupled to the fastener 144 of the article of clothing 140. Likewise, the fastener 115 of the flexible leaf 110 may be coupled to the fastener 145 of the article of clothing 140. Electrical power may then be generated at the solar cell 112. The electrical power may be transmitted to the battery charger circuit 142 via the fasteners 114, 115 of the flexible leaf 110 and the fasteners 144, 145 of the article of clothing 140. The battery 148 may be at least partially charged via the battery charger circuit 142 and the charged battery 148 may be used to power the propulsion system 150, the environmental control system 151, the communication system 152, another type of electrical system that may be incorporated into the article of clothing 140, or any combinations thereof.

Further, the flexible leaf 110 may subsequently be uncoupled from the article of clothing 140 by uncoupling the fastener 114 from the fastener 144 and uncoupling the fastener 115 from the fastener 145. Another flexible leaf (not shown), having its own set of fasteners, may be coupled to the article of clothing 140 in place of the flexible leaf 110. This enables the system 100 to have a modular design.

A benefit of the system 100 is that by including the solar cell 112 in a flexible leaf 110 that is attachable to the article of clothing 140, the article of clothing 140 may generate electrical power. In the case of a spacesuit, the generated electrical power may supplement power stored in the battery 148 and increase the potential duration of extravehicular missions in low earth orbit. In some cases, the article of clothing 140 may be self-sufficient in generating electrical power. Further, the flexible design of the flexible leaf 110 may enable to flexible leaf 110 to be positioned on portions of the body of a wearer that would otherwise be unsuitable for attaching rigid solar cells. As an additional benefit, the modular design of the flexible leaf 110 may simplify the process of changing and/or reconfiguring solar cells used to power the battery charger circuit 142. Other advantages may exist.

Referring to FIG. 2, an embodiment of a flexible leaf 110 is depicted. In addition to the solar cell 112 and the fasteners 114, 115, the flexible leaf 110 may include a fabric pocket 202 and a transparent shield 204. The fabric pocket 202 may include a polyester material or another type of natural or synthetic fabric (e.g., carbon fiber, glass fiber, Kevlar) and may have a plain weave with a window defined therein. Alternatively, other weaves may be used, such as harness, satin, or 3 or 8-foot crow weaves in order to enhance or otherwise alter the flexibility of the flexible leaf 110.

The transparent shield 204 may include polyvinyl plastic or another type of other transparent material and may be attached to the window of the fabric pocket 202 with thread 206. The thread 206 may include nylon or other types of natural or synthetic fibers. The thread 206 may be 0.063-inch thread. Although not depicted in FIG. 2, the wires 118 (depicted in FIG. 1) may also be attached to the fabric pocket 202 with nylon thread. The flexible leaf 110 may omit any type of polymer adhesive.

An advantage of the flexible leaf 110 is that by omitting polymer adhesives, the flexible leaf 110 may be more durable for space travel and the extremes in temperature and radiation associated with low earth orbit. However, it should be noted, that despite this benefit in some applications, adhesive may be used instead of, or in addition to, the thread 206. Further, the fabric pocket 202 and the transparent shield 204 may protect the solar cell 112 from dust, or other hazards, while in use. Other advantages may exist.

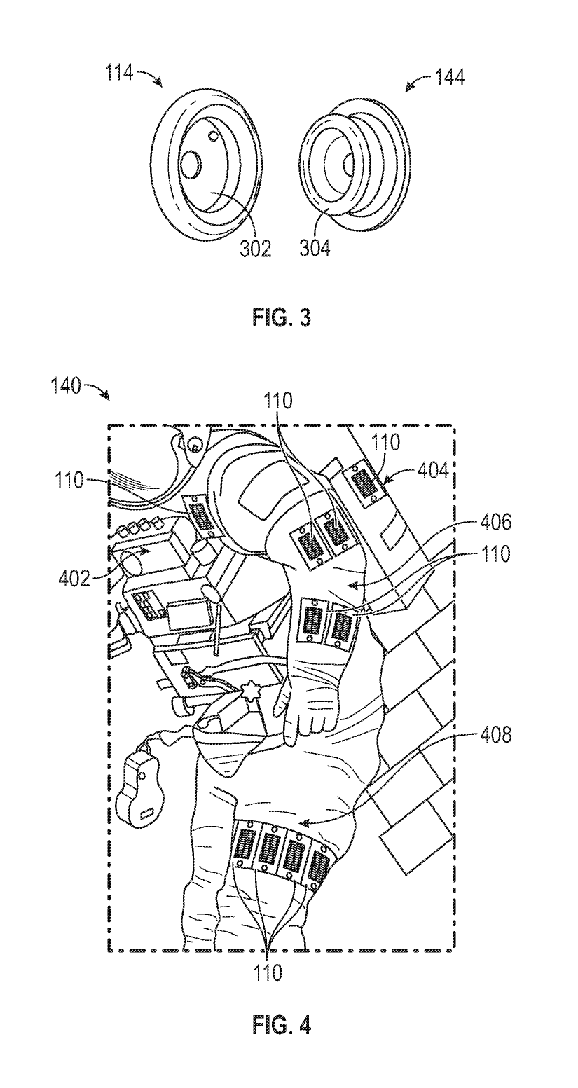

Referring to FIG. 3, embodiments of fasteners 114, 144 are depicted. The fastener 114 may have a first shape and the fastener 144 may have a second shape that is complementary to, and configured to interlock with, the first shape. For example, the fastener 114 may be a snap fastener, as depicted in FIG. 3, and may have a socket 302. The fastener 144 may also be a snap fastener and may have a stud 304. The stud 304 may be snapped into the socket 302. The fasteners 114, 144 may be electrically conductive to form an electrical connection between a circuit (e.g., the solar cell 112) coupled to the fastener 114 and another circuit (e.g., the battery charger circuit 142) coupled to the fastener 144. In an embodiment, the fasteners 114, 144 are made from bronze. Other conductive material may also be used. Although FIG. 3 is described with reference to the fasteners 114, 115, the same snap fasteners may be used to implement the fasteners 115, 145 as well. In an embodiment, the fasteners 114, 144 are heavy-duty bronze snaps (size #24, ⅝ inch). Further, although FIG. 3 depicts the fasteners 114, 144 as snap fasteners, different geometries and different types of fasteners may also be used. For example, the fasteners 114, 144 may include metal-to-metal snap style buttons, plastic snaps with metal contacts at mating surfaces, or combinations of different types of fasteners.

Referring to FIG. 4, an embodiment of an article of clothing 140 is depicted. In this embodiment, the article of clothing is a spacesuit, although other applications are contemplated by the disclosure. The article of clothing 140 may be configured to have multiple implementations of the flexible leaf 110 attached thereto. Although not depicted, each of the implementations of the flexible leaf 110 may attach to the spacesuit via a pair of fasteners as described herein.

As shown in FIG. 4, implementations of the flexible leaf 110 may be attached to portions of the article of clothing 140 that are configured to be worn on a wearers chest 402, back 404, arm 406, leg 408, or any combination thereof. The amount of power generated at the article of clothing 140 may be dependent on available surface area for coverage by the implementations of the flexible leaf 110. A typical human body surface area may be calculated as follows:

$$Body Surface Area ( {m}^{2} ) = \sqrt{\frac{height ( cm ) \times weight ( kg )}{3600 ( cm kg / {m}^{2} )}}$$

For an average adult, the typical body surface area may be approximately 1.95 m². At any given time, however, less than 50% of the body may be illuminated by direct sunlight. As such, the placement, flexibility, and size of each implementation of the flexible leaf 110 may have a significant effect on power generation. For the greatest benefit, implementations of the flexible leaf 110 may be positioned on the chest 402, the leg 408, and the shoulder portion of the arm 406. Illumination of half of the legs 408 and the majority of the chest 402 may provide up to about 0.36 m² of surface area for power generation. Thus, a significant amount of power generation is possible.

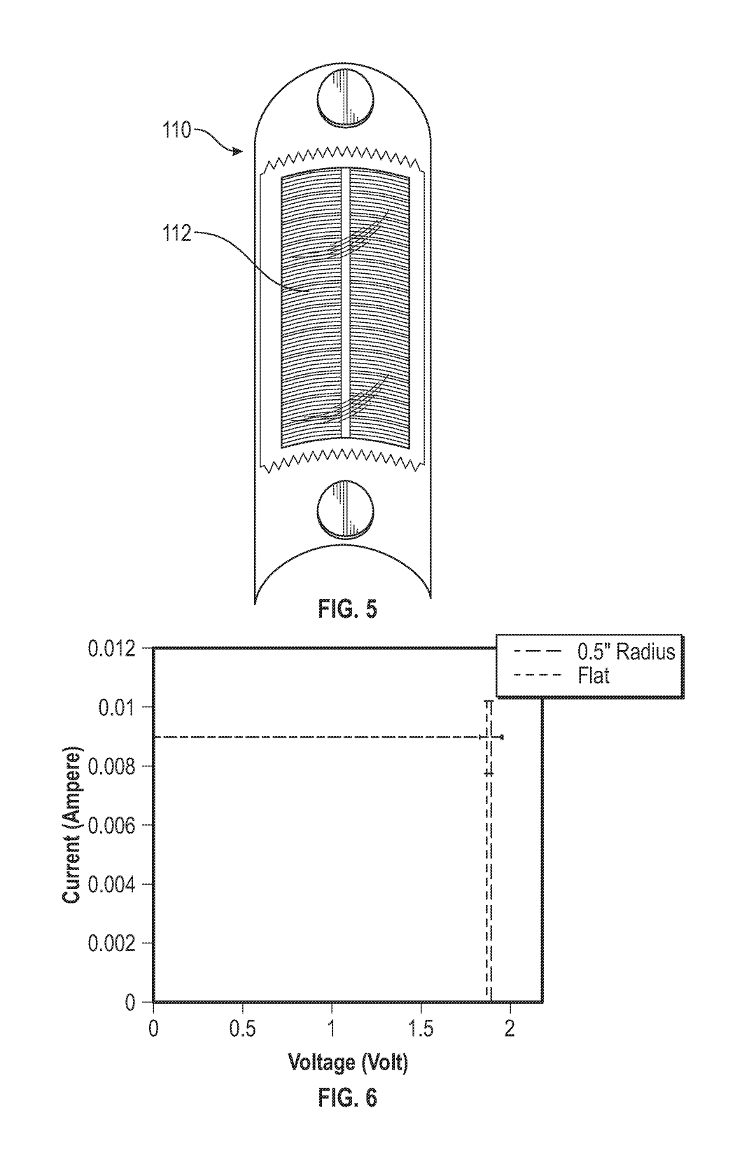

Referring to FIG. 5 an embodiment of a flexible leaf 110 having a solar cell 112 is depicted in an experimental setup, being bent in an arc pattern having a radius of 0.5 inches. Current and voltage measurements may be taken in this setup for comparison with a solar cell that is not bent. The solar cell 112 of the embodiment of FIG. 5 may be a triple junction Gallium-Arsenide solar cell. During measurements, a light source-isolating black box was used along with a Blue-Lux 10,000 Flux Full spectrum 93 Color Rendering Index 5500 K light source. The light source was selected to match natural light (e.g., AM1.5 standard conditions). The “stand-off” distance from the solar cell 112 to the source was 3 inches. A standard multi-meter was used to measure current and voltage.

FIG. 6 depicts results of the test configuration of FIG. 5. As shown in FIG. 5, there is very little difference in operation of the flexible solar leaf with respect to current and voltage production. Thus, FIG. 6 shows that flexible triple-junction Gallium-Arsenide solar cells are particularly useful in powered clothing (e.g., spacesuit) applications because of their tolerance to flexing with little change to electrical output. Other advantages may exist.

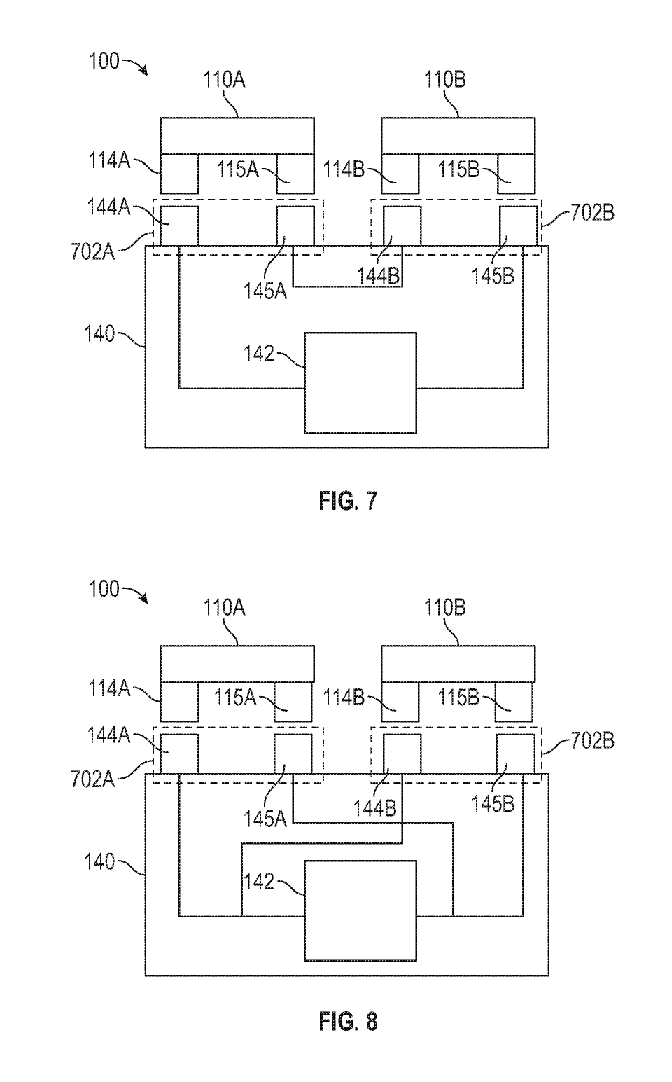

Referring to FIG. 7, an embodiment of the system 100 is depicted in which a first flexible leaf 110A and a second flexible leaf 110B are coupled to a battery charger circuit 142 in series with each other. Although not depicted, both of the flexible leaves 110A, 110B may have solar cells as described herein.

The first flexible leaf 110A may include a first fastener 114A and a second fastener 115A. The article of clothing 140 may likewise include a first pair of fasteners 702A including a first fastener 144A and a second fastener 145A that correspond to the fasteners 114A, 115A. Likewise, the second flexible leaf 110B may include a first fastener 114B and a second fastener 115B. The article of clothing 140 may include a second pair of fasteners 702B including a first fastener 144B and a second fastener 145B that correspond to the fasteners 114B, 115B. This particular configuration may be used to take advantage of the additive properties of the voltage output of the flexible leaves 110A, 110B. Although FIG. 7 depicts two flexible leaves 110A, 110B, the battery charger circuit 142 of the article of clothing 140 may be configured to couple in series to more than two flexible pockets.

Referring to FIG. 8, an embodiment of the system 100 is depicted in which a first flexible leaf 110A and a second flexible leaf 110B are coupled to a battery charger circuit 142 in parallel with each other. This particular configuration may be used to take advantage of the additive properties of the electrical current output of the flexible leaves 110A, 110B. Although FIG. 8 depicts two flexible leaves 110A, 110B, the battery charger circuit 142 of the article of clothing 140 may be configured to couple in parallel to more than two flexible pockets.

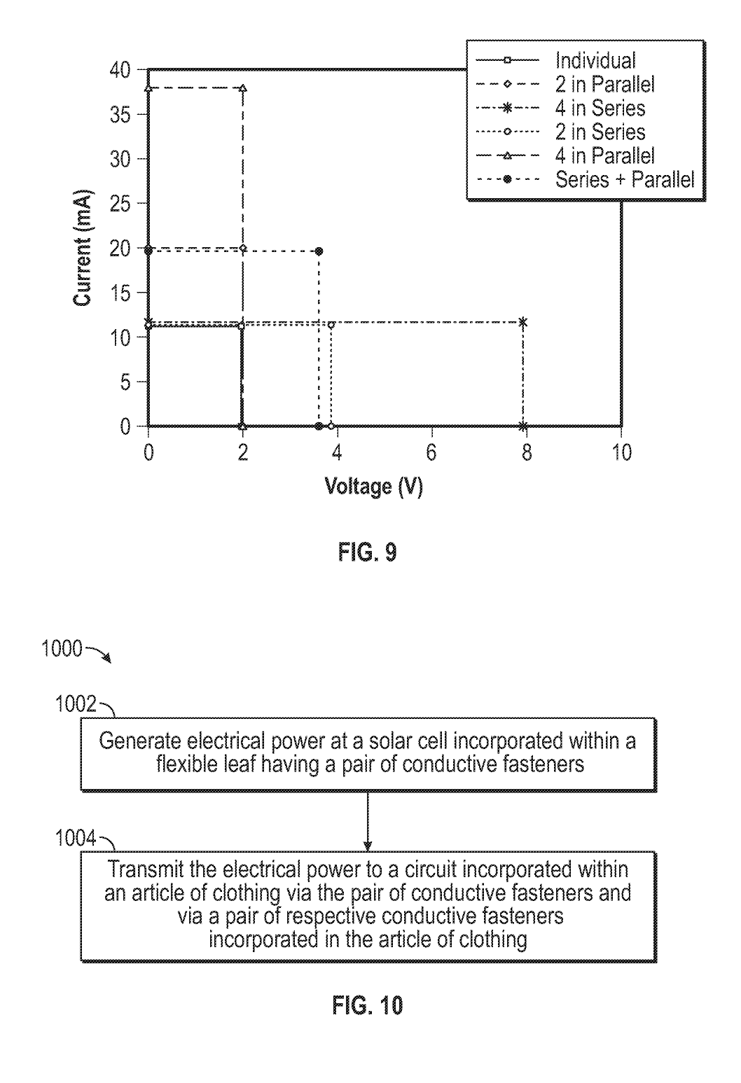

Referring to FIG. 9, results of testing data from various series and parallel configurations of multiple implementations of the flexible leaf 110 are depicted. As shown in FIG. 9, an individual leaf, as described herein, may provide up to about 11 mA of current and about 2 V. Two leaves in a parallel configuration (e.g., the configuration depicted in FIG. 8) may provide up to about 20 mA of current and about 2 V. Four leaves in a parallel configuration may provide up to about 37 mA of current and about 2V. Two leaves in a series configuration (e.g., the configuration depicted in FIG. 7) may provide up to about 11 mA electrical current and almost 4 volts. Four leaves in a series configuration may provide up to about 11 mA electrical current and almost 8 volts. Four leaves in a configuration where two pairs of serial leaves are configured in parallel, or a similar circuit where two pairs of parallel leaves are configured in series, may provide up to about 20 mA and almost 4 volts. The different configurations of leaves may be changed based on a particular application to provide a desired combination of electrical current and voltage.

Referring to FIG. 10, a method 1000 is depicted. The method 1000 may include generating electrical power at a solar cell incorporated within a flexible leaf having a pair of conductive fasteners, at 1002. For example, the solar cell 112 may be used at the flexible leaf 110 to generate electrical power. As described herein, the flexible leaf 110 may have a pair of fasteners 114, 115.

The method 1000 may further include transmitting the electrical power to a circuit incorporated within an article of clothing via the pair of conductive fasteners and via a pair of respective conductive fasteners incorporated in the article of clothing, at 1004. For example, the generated electrical power may be transmitted to the battery charger circuit 142 within the article of clothing 140 via the fasteners 144, 145.

A benefit of the method 1000 is that electrical power may be generated for use at an article of clothing 140 at a removable, and interchangeable, flexible leaf. Other advantages may exist.

Although various embodiments have been shown and described, the present disclosure is not so limited and will be understood to include all such modifications and variations as would be apparent to one skilled in the art.

What is claimed is:

1. A system comprising:
a flexible leaf having a fastener, the fastener being electrically conductive, the flexible leaf having a solar cell incorporated therein, the solar cell electrically coupled to the fastener;
an article of clothing including a respective fastener, the respective fastener being electrically conductive, the flexible leaf configured to couple to the article of clothing via at least the fastener and the respective fastener; and
an electrical circuit incorporated in the article of clothing, the electrical circuit electrically coupled to the respective fastener.

2. The system of claim 1, wherein the fastener is a snap fastener having a first shape, and wherein the respective fastener is a complementary snap fastener having a second shape, the first shape configured to interlock with the second shape.

3. The system of claim 1, further comprising:
a second fastener incorporated in the flexible leaf, the second fastener being electrically conductive; and
a respective second fastener incorporated in the article of clothing, the respective second fastener being electrically conductive, wherein the solar cell and the electrical circuit are configured to form at least a portion of a closed circuit loop in response to the fastener being fastened to the respective fastener and the second fastener being fastened to the respective second fastener.

4. The system of claim 1, wherein the article of clothing is a portion of a space suit.

5. The system of claim 1, wherein the electrical circuit includes at least a battery configured to be charged at least partially by the solar cell.

6. The system of claim 5, wherein the battery is configured to power a propulsion system, an environmental control system, a communication system, or any combinations thereof.

7. The system of claim 1, wherein the solar cell is a multi junction Gallium-Arsenide solar cell.

8. The system of claim 1, wherein the flexible leaf includes a fabric pocket.

9. The system of claim 1, wherein the flexible leaf includes a transparent shield.

10. The system of claim 9 wherein the transparent shield is attached to the flexible leaf with thread, the flexible leaf omitting any polymer adhesive.

11. The system of claim 9, wherein the transparent shield is attached to the flexible leave with adhesive.

12. The system of claim 1, wherein the article of clothing includes a leg portion, a chest portion, a back portion, an arm portion, or any combination thereof, wherein the respective fastener is positioned on the leg portion, on the chest portion, on the back portion, or on the arm portion.

13. A system comprising:
a plurality of flexible leaves, each flexible leaf having a pair of conductive fasteners incorporated therein;
a plurality of solar cells, each of the flexible leaves having at least one of the solar cells incorporated therein; and
an article of clothing including multiple pairs of conductive fasteners incorporated therein, wherein the plurality of flexible leaves are configured to interchangeably connect to each pair of fasteners.

14. The system of claim 12, wherein the multiple pairs of conductive fasteners are electrically coupled to an electrical circuit in series with each other.

15. The system of claim 12, wherein the multiple pairs of fasteners are electrically coupled to an electrical circuit in parallel with each other.

16. A method comprising:
generating electrical power at a solar cell incorporated within a flexible leaf having a pair of conductive fasteners; and
transmitting the electrical power to a circuit incorporated within an article of clothing via the pair of conductive fasteners and via a pair of respective conductive fasteners incorporated in the article of clothing.

17. The method of claim 15, further comprising, before generating the electrical power:
coupling a first conductive fastener of the pair of conductive fasteners with a first respective conductive fastener of the pair of respective conductive fasteners; and
coupling a second conductive fastener of the pair of conductive fasteners with a second respective conductive fastener of the pair of respective conductive fasteners.

18. The method of claim 15, further comprising:
uncoupling a first conductive fastener of the pair of conductive fasteners from a first respective conductive fastener of the pair of respective conductive fasteners; and
uncoupling a second conductive fastener of the pair of conductive fasteners from a second respective conductive fastener of the pair of respective conductive fasteners.

19. The method of claim 15, further comprising:
uncoupling the flexible leaf from the article of clothing and coupling a second flexible leaf to the article of clothing, the second flexible leaf having a second pair of conductive fasteners.

20. The method of claim 15, further comprising:
charging a battery via the circuit incorporated within the article of clothing.
